(19) United States
(12) Patent Application Publication
(10) Pub. No.: US 2021/0028181 A1
(43) Pub. Date: Jan. 28, 2021

(54) SEMICONDUCTOR DEVICE AND FABRICATION METHOD THEREOF

(71) Applicant: Hexas Technology Corp., New Taipei City (TW)

(72) Inventors: Chen-Chih WANG, New Taipei City (TW); Li-Wei HO, New Taipei City (TW); Yeu-Yang WANG, New Taipei City (TW)

(21) Appl. No.: 16/936,401

(22) Filed: Jul. 22, 2020

(30) Foreign Application Priority Data
Jul. 24, 2019 (TW) 108126230

(51) Int. Cl. H01L 27/11521; H01L 27/11519; H01L 27/11556; H01L 27/11565; H01L 27/11568; H01L 27/11582

(52) U.S. Cl. CPC H01L 27/11521; H01L 27/11519; H01L 27/11582; H01L 27/11565; H01L 27/11568; H01L 27/11556

(57) ABSTRACT

The disclosure provides a semiconductor device and a fabrication method thereof. The semiconductor device includes a substrate, a first and second polysilicon layers on the substrate, a third polysilicon layer between the first and the second polysilicon layers, a first isolation layer adjacent with the first to the third polysilicon layers, a gate dielectric layer and a gate conductive layer embedded in the third polysilicon layer, a second isolation layer on the gate conductive layer and the third polysilicon layer. The third polysilicon layer has a concave portion between the first and the second polysilicon layers, and the concave portion is defined as a main body. The main body includes a bulk region. The gate conductive layer facing toward the concave portion serves as a gate.

### RELATED APPLICATIONS

This application claims priority to Taiwan Application Serial Number 108126230, filed Jul. 24, 2019, which is herein incorporated by reference in its entirety.

### BACKGROUND

### Technical Field

The present disclosure relates to a semiconductor device and a fabrication method thereof.

### Description of Related Art

Semiconductor memory devices may be classified into two categories, volatile memory devices and nonvolatile memory devices. In contrast to volatile memory devices, nonvolatile memory devices are widely used in program coding, embedded system, solid state devices (SSD), IoT, artificial intelligence (AI), and cloud storage because nonvolatile memory devices do not require power to retain data.

Flash memory is a type of nonvolatile memory devices and has various advantages, such as light weight, small size and low power. As a result, the flash memory is widely used in various personal computers, consumer electronics products and communications products, such as laptops, digital televisions, and mobile communications devices. However, NOR Flash has fast read speed, but has slow write speed. Therefore, performance and density of NOR Flash is still needed to be improved.

### SUMMARY

According to some embodiments of the present disclosure, a method of forming a semiconductor device includes following steps. A stack of a first polysilicon layer, a silicon nitride layer, and a second polysilicon layer are formed. A first trench is formed penetrating the stack, wherein the first trench has a serpentine shape, in a top view. A first isolation is filled in the first trench. A second trench is formed penetrating the stack to expose sidewalls of the first polysilicon layer, the silicon nitride layer, and the second polysilicon layer. The silicon nitride layer is removed to form a first recess between the first polysilicon layer and the second polysilicon layer. Exposed sidewalls of the first polysilicon layer and the second polysilicon layer are doped to define a source terminal contact and a drain terminal contact. A third polysilicon layer is formed on the first polysilicon layer, the second polysilicon layer and in the first recess between the first polysilicon layer and the second polysilicon layer, such that the third polysilicon layer has a concave portion between the first polysilicon layer and the second polysilicon layer. The concave portion is doped to define a source region and a drain region. An inside of the concave portion is doped to form a well region, and the well region serves as a bulk region. The bulk region faces toward the first trench. The concave portion is doped to define a channel region. The concave portion is defined as a main body of a memory device. A gate dielectric layer is formed on the third polysilicon layer. A gate conductive layer is formed on the gate dielectric layer, and the gate conductive layer is defined as a word line. The gate conductive layer in the first recess serves as a gate which faces toward the second trench. A second isolation layer is formed on the gate conductive layer.

According to some embodiments of the present disclosure, the method further includes following steps. A third isolation layer is formed on the first isolation layer and the second isolation layer. The third isolation layer is etched to form a first via hole. Conductive materials are filled in the first via hole to form a first via contact. The first via contact is disposed on the drain terminal contact. A fourth isolation layer is formed on the third isolation layer. The fourth isolation layer is etched to form a second recess. Conductive materials are filled in the second recess to form an interconnect conductive pad. The interconnect conductive pad is disposed in the fourth isolation layer. A fifth isolation layer is formed on the fourth isolation layer and the interconnect conductive pad. The fifth isolation layer is etched to form a second via hole. Conductive materials are filled in the second via hole to form a second via contact.

According to some embodiments of the present disclosure, the method further includes forming a drain conductive layer on the fifth isolation layer and the second via contact. The drain conductive layer is defined as a bit line.

According to some embodiments of the present disclosure, a length direction of the second isolation layer is parallel to a length direction of the first isolation layer.

According to some embodiments of the present disclosure, the third polysilicon layer further has a first portion and a second portion connected to the concave portion, the first portion and the second portion are respectively on the first polysilicon layer and the second polysilicon layer.

According to some embodiments of the present disclosure, the interconnect conductive pad is connected to the first via contact and the second via contact.

According to some embodiments of the present disclosure, the first via contact is aligned with the drain terminal contact.

According to some embodiments of the present disclosure, the semiconductor device includes a substrate, a first and a second polysilicon layers on the substrate, a third polysilicon layer between the first and the second polysilicon layers, a first isolation layer adjacent with the first to the third polysilicon layers, a gate dielectric layer and a gate conductive layer embedded in the third polysilicon layer, a second isolation layer on the gate conductive layer and the third polysilicon layer. The third polysilicon layer has a concave portion between the first and the second polysilicon layers, and the concave portion is defined as a main body of a memory device. The main body includes a source region, a drain region, a channel region, and a bulk region. The first isolation layer has a serpentine shape, in a top view. The gate conductive layer facing toward the concave portion serves as a gate. The bulk region and the gate respectively face toward the first isolation layer and the second isolation layer.

According to some embodiments of the present disclosure, the semiconductor device further includes a third isolation layer, a first via contact, a fourth isolation layer, an interconnect conductive pad, the fifth isolation layer, and a second via contact. The third isolation layer is disposed on the first isolation layer and the second isolation layer. The first via contact is disposed on the third isolation layer. The fourth isolation layer is disposed on the third isolation layer. The interconnect conductive pad is disposed in the fourth isolation layer. The fifth isolation layer is disposed on the fourth isolation layer. The second via contact is deposed in the fifth isolation layer.

According to some embodiments of the present disclosure, the interconnect conductive pad is in contact with the first via contact and the second via contact.

According to some embodiments of the present disclosure, the first via contact and the second via contact are made of same materials.

According to some embodiments of the present disclosure, the first via contact, the interconnect conductive pad, and the gate conductive layer are defined as a group of a NOR flash memory cell. The group of the NOR flash memory cell includes two NOR flash memory cells. An area density of each of the NOR flash memory cells is less than six times a square of a feature size, per cell.

According to some embodiments of the present disclosure, the semiconductor device further includes a drain conductive layer on the fifth isolation layer and the second via contact. The drain conductive layer is defined as a bit line.

According to some embodiments of the present disclosure, the first isolation layer has a serpentine shape, and the main body of the memory device is arranged antisymmetrically on the first isolation layer, in the top view.

According to some embodiments of the present disclosure, the second isolation layer has a strip shape, in the top view.

According to some embodiments of the present disclosure, the semiconductor device further includes a fourth polysilicon layer on the substrate. The fourth polysilicon layer is defined as a common ground line.

According to some embodiments of the present disclosure, the third polysilicon layer covers the first polysilicon layer and the second polysilicon layer. The concave portion of the third polysilicon layer has a semi-elliptical profile, in the top view.

According to some embodiments of the present disclosure, an edge of the third polysilicon layer is aligned with an edge of the gate conductive layer.

According to some embodiments of the present disclosure, a vertical projection region of the first via contact on the substrate is not fully overlapped with a vertical projection region of the second via contact on the substrate.

In summary, the disclosure provides the semiconductor device and the fabrication method of the semiconductor device. By using the aforementioned semiconductor device, a density of the semiconductor device can be increased, thereby improving a performance of the semiconductor device.

It is to be understood that both the foregoing general description and the following detailed description are by examples, and are intended to provide further explanation of the invention as claimed.

### BRIEF DESCRIPTION OF THE DRAWINGS

Embodiments of the present disclosure can be more fully understood by reading the following detailed description of the embodiment, with reference made to the accompanying drawings as follows.

FIGS. 1, 2, 3A, 4A, 5A, 6, 7, 8A, 9, 10A, 11A, 12A, 13A, 14, 15, 16, 17A, 18A and 21A are cross-sectional views of various stages in the fabrication of a semiconductor device in accordance with some embodiments of the present disclosure.

FIGS. 3B, 4B and 5B are top views of the semiconductor device respectively taken along a horizontal level of a silicon nitride layer of FIGS. 3A, 4A, and FIG. 5A.

FIGS. 8B, 10B, 11B and 12B are top views of the semiconductor device respectively taken along a horizontal level of a removed silicon nitride layer of FIGS. 8A, 10A, 11A and FIG. 12A.

FIG. 11C is a schematic view of a memory cell of the transistor device of FIG. 11B.

FIG. 13B is a top view of the semiconductor device taken along a horizontal level of a first via contact of FIG. 13A.

FIG. 17B is a top view of the semiconductor device taken along a horizontal level of an interconnect conductive pad of FIG. 17A.

FIG. 18B is a top view of the semiconductor device taken along a horizontal level of a second via contact of FIG. 18A.

FIG. 19 is a cross-sectional view of the semiconductor device taken along line 1-1 of FIG. 18B.

FIG. 20 is a cross-sectional view of the semiconductor device taken along line 2-2 of FIG. 18B.

FIG. 21B is a top view of the semiconductor device taken along a horizontal level of a drain conductive layer of FIG. 21A.

FIG. 22 is a circuit diagram of a NOR flash memory cell array in accordance with some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

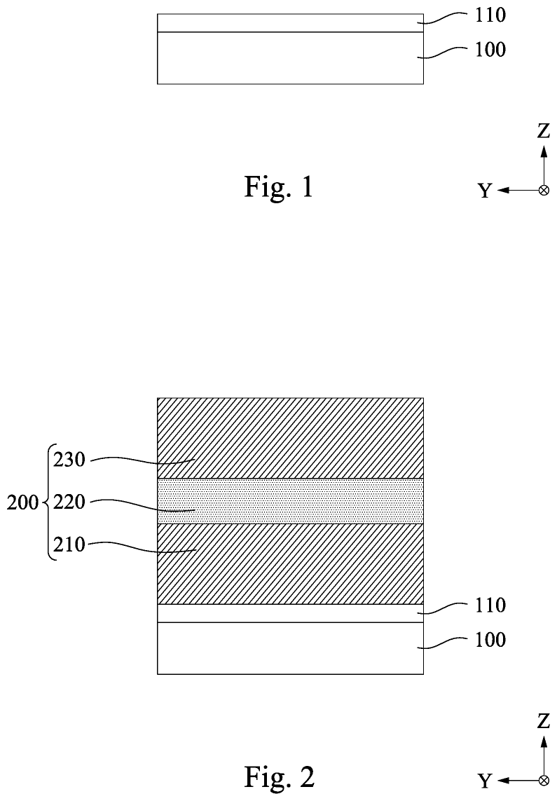

FIGS. 1, 2, 3A, 4A, 5A, 6, 7, 8A, 9, 10A, 11A, 12A, 13A, 14, 15, 16, 17A, 18A and 21A are cross-sectional views of various stages in the fabrication of a semiconductor device in accordance with some embodiments of the present disclosure.

Referring to FIG. 1 and FIG. 2, a first polysilicon layer 110 is formed on the substrate 100, and a stack 200 is formed on the first polysilicon layer 110. The first polysilicon layer 110 is defined as a common ground line. In some embodiments, the stack 200 includes a second polysilicon layer 210, a silicon nitride layer 220 and a third polysilicon layer 230. In other words, the second polysilicon layer 210, the silicon nitride layer 220 and the third polysilicon layer 230 is in sequence arranged on the substrate 100. The second polysilicon layer 210 closest to the substrate 100 directly contacts the first polysilicon layer 110.

In some embodiments, the substrate 100 is a silicon substrate. In other embodiments, the substrate 100 may include another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In yet another alternative, the substrate 100 is a SOI such as having a buried layer.

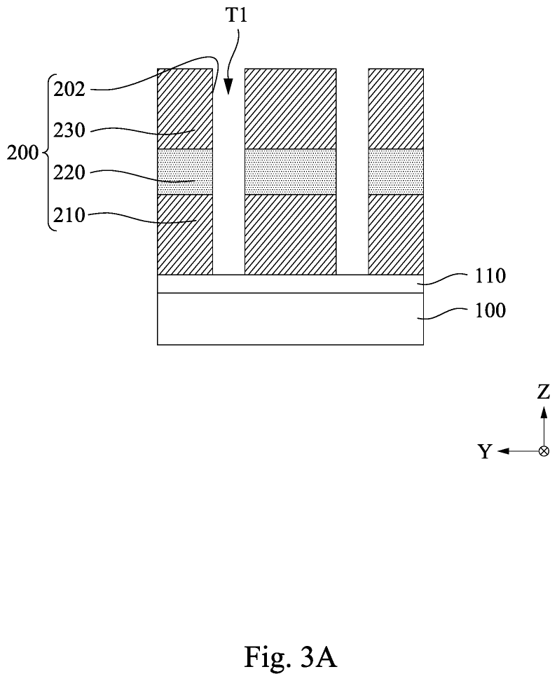

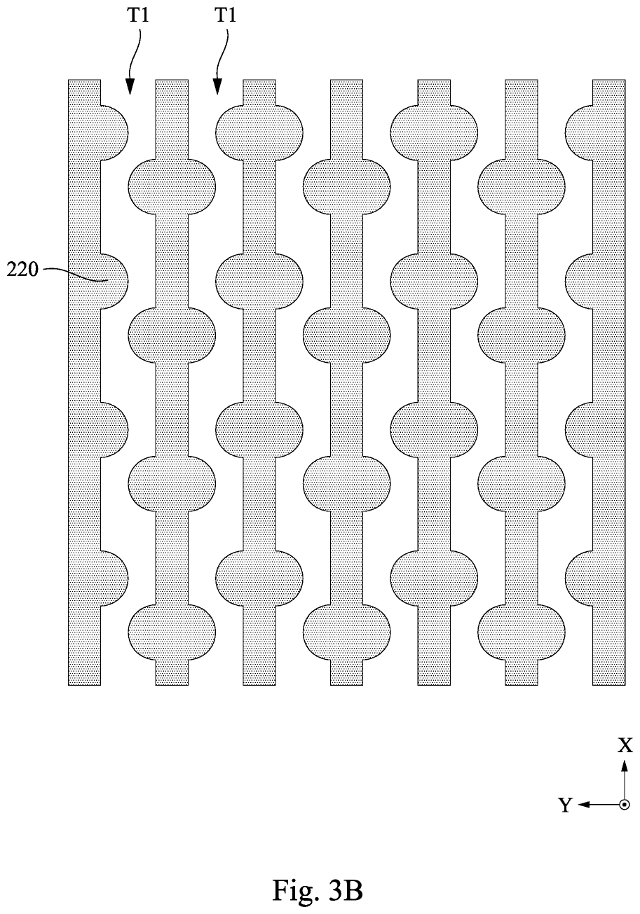

Referring to FIGS. 3A and 3B, FIG. 3B is a top view of the semiconductor device respectively taken along a horizontal level of the silicon nitride layer 220 of FIG. 3A. After the stack 200 is formed, a portion of the stack 200 is etched to form a first trench T1 penetrating the stack 200. In greater details, a patterned hard mask layer may be formed on the stack 200 by a suitable deposition, developing, and/or etching technique, and the patterned hard mask layer may be used as an etch mask to etch the stack 200. The etching of the stack 200 terminates at the first polysilicon layer 110. In other words, the first trench T1 is formed, such that sidewalls 202 are exposed. The first trench T1 exposes the underlying first polysilicon layer 110. In some embodiments, the first trench T1 has a serpentine shape, as shown in FIG. 3B. In greater details, the first trench T1 has an S-shaped profile in the top view (FIG. 3B).

In some embodiments, an end point detection technique may be used in determining stopping of the stack 200 during the etching process. The etching process may use either dry or wet etching. When dry etching is used, the process gas may include CF₄, CHF₃, NF₃, SF₆, Br₂, HBr, Cl₂, or combinations thereof. Diluting gases such as N₂, O₂, or Ar may optionally be used. When wet etching is used, the etching solution (etchant) may include NH₄OH:H₂O₂:H₂O (APM), NH₂OH, KOH, HNO₃:NH₄F:H₂O, and/or the like.

In some embodiments, the first trench T1 in FIG. 3B is arranged antisymmetrically with another adjacent first trench T1. In greater details, as shown in FIG. 3B, one of the first trenches T1 (e.g., the first trench T1 on the left side) has an inverse S-shaped profile, and another adjacent first trench T1 (e.g., the first trench T1 on the right side) has an S-shaped profile. Alternatively, one of the first trenches T1 may have an S-shaped profile, and another adjacent first trench T1 may have the inverse S-shaped profile. In some embodiments, one of the first trenches T1 may be arranged symmetrically with another adjacent first trench T1. For example, one of the first trenches T1 may have an S-shaped profile, and another adjacent first trench T1 may have an S-shaped profile. Alternatively, one of the first trenches T1 may have an inverse S-shaped profile, and another adjacent first trench T1 may have the inverse S-shaped profile.

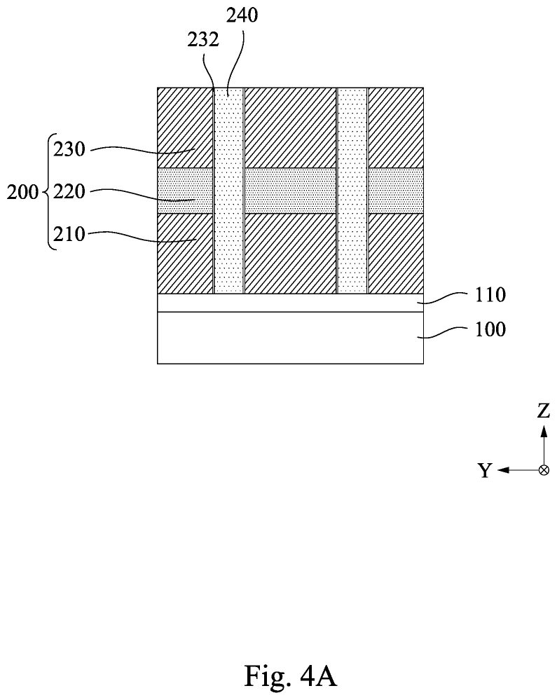

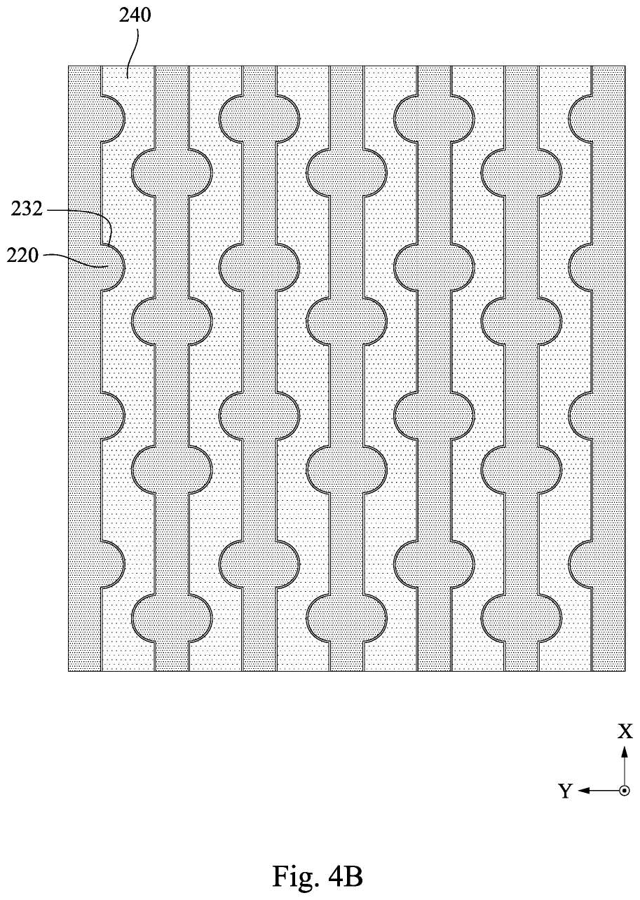

Referring to FIG. 4A and FIG. 4B, FIG. 4B is a top view of the semiconductor device respectively taken along the horizontal level of a silicon nitride layer 220 of FIG. 4A. A liner layer 232 is formed on the exposed sidewall 202 (see FIG. 3A) of the stack 200. The liner layer 232 may be made of silicon nitride or other suitable insulating materials. After the liner layer 232 is formed, the trench T1 (see FIG. 3A) is then filled with insulating materials to form a first isolation layer 240. In some embodiments, after the first isolation layer 240 is formed, a planarization process, such as a CMP process, may be performed to remove excess materials of the liner layer 232 and/or the first isolation layer 240. In some embodiments, the first isolation layer 240 includes silicon oxide layer, silicon nitride layer or silicon oxynitride layer, and the like. The first isolation layer 240 may be made of low-k dielectric material, such as tetraethoxysilane (TEOS). The first isolation layer 240 may be formed by CVD, PECVD, ALD, FCVD, LPCVD, or other suitable methods.

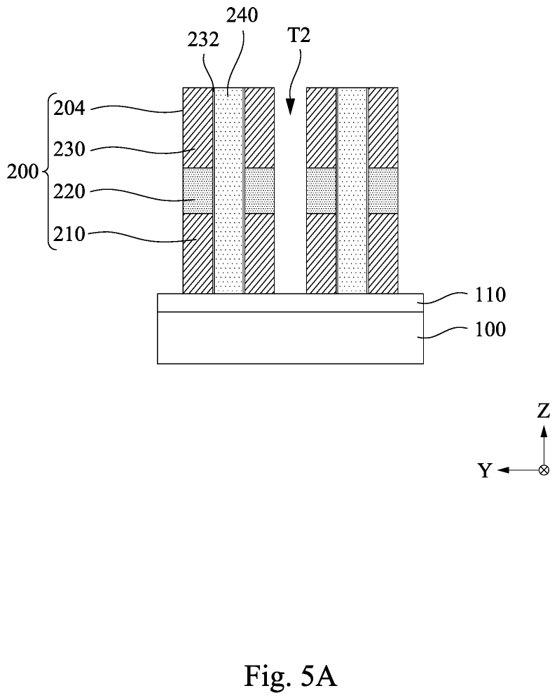

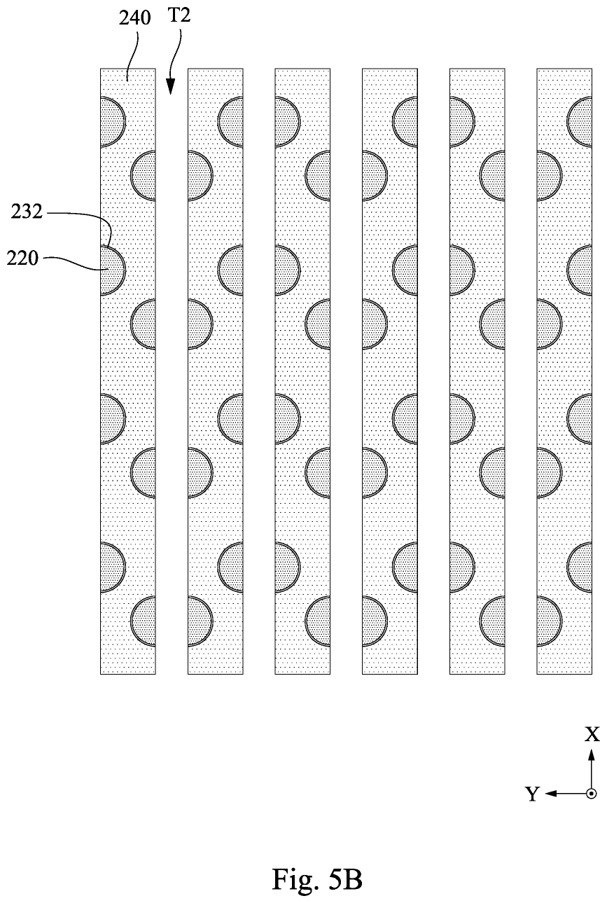

Referring to FIG. 5A and FIG. 5B, FIG. 5B is a top view of the semiconductor device respectively taken along the horizontal level of a silicon nitride layer 220 of FIG. 5A. After the first isolation layer 240 is formed, another etching process is performed to form a second trench T2 penetrating the stack 200 to expose sidewalls 204 of the second polysilicon layer 210, the silicon nitride layer 220, and the third polysilicon layer 230. In greater details, a patterned hard mask layer may be formed on the stack 200 by a suitable deposition, developing, and/or etching technique, and the patterned hard mask layer may be used as an etch mask to etch the stack 200. In other words, the trench T2 penetrates the second polysilicon layer 210, the silicon nitride layer 220, and the third polysilicon layer 230. In some embodiments, as shown in FIGS. 3B and 5B, the second trench T2 has a stripe shape, different from the serpentine shape of the first trench T1.

In some embodiments, the etching of the stack 200 terminates at the first polysilicon layer 110. In other word, the trench T2 exposes the underlying first polysilicon layer 110. In some embodiments, an end point detection technique may be used in determine stopping of the stack 200 during the etching process. The etching process may use either dry or wet etching. When dry etching is used, the process gas may include CF₄, CHF₃, NF₃, SF₆, Br₂, HBr, Cl₂, or combinations thereof. Diluting gases such as N₂, O₂, or Ar may optionally be used. When wet etching is used, the etching solution (etchant) may include NH₄OH:H₂O₂.H₂O (APM), NH₂OH, KOH, HNO₃:NH₄F:H₂O, and/or the like.

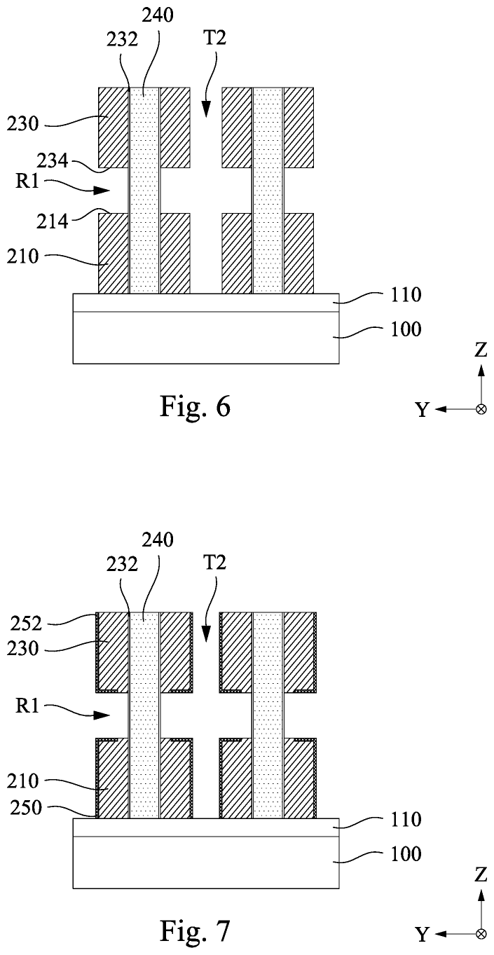

Referring to FIG. 6, a removing process is performed to form a first recess R1. In greater details, the silicon nitride layer 220 (see FIG. 5A) is removed to form the first recess R1 between the second polysilicon layer 210 and the third polysilicon layer 230. Since the first recess R1 is formed, one portion of the liner layer 232 is exposed. In other words, one portion of the liner layer 232 is exposed by the first recess R1, while the other portion of the liner layer 232 is covered by the second polysilicon layer 210 and the third polysilicon layer 230. In some embodiments, the first recess R1 communicates with the second trench T2. In some embodiments, after the first recess R1 is formed, a side 214 of the second polysilicon layer 210 and a side 234 of the third polysilicon layer 230 are exposed.

Referring to FIG. 6 and FIG. 7, after the first recess R1 is formed, the exposed sidewalls 204 of the second polysilicon layer 210 and the third polysilicon layer 230 are doped to define a source terminal contact 250 and a drain terminal contact 252. In greater details, an ion implantation process is performed to the exposed sidewalls 204 of the second polysilicon layer 210 and the third polysilicon layer 230, followed by an annealing process to activate the implanted dopants. In some embodiments, doping the exposed sidewalls 204 further includes doping a side 214 of the second polysilicon layer 210 at the first recess R1 and doping the side 234 of the third polysilicon layer 230 at the first recess R1. In greater details, one portion of the side 214 of the second polysilicon layer 210 is doped, while the other portion of the side 214 of the second polysilicon layer 210 is not doped. Similarly, one portion of the side 234 of the third polysilicon layer 230 is doped, while the other portion of the side 234 of the third polysilicon layer 230 is not doped. In some embodiments, dopants of doping the exposed sidewalls 204 to define the source terminal contact 250 and the drain terminal contact 252 may include P-type dopants or N-type dopants. For example, P-type dopants may be boron (B), BF₂ or BF₃, and N-type dopants may be phosphorous (P), arsenic (As), or antimony (Sb). In the present embodiments, the source terminal contact 250 and the drain terminal contact 252 include N-type dopants. In some embodiments, the source terminal contact 250 and the drain terminal contact 252 are disposed on the different sides of the first recess R1. Stated differently, the source terminal contact 250 and the drain terminal contact 252 are separated apart by the first recess R1.

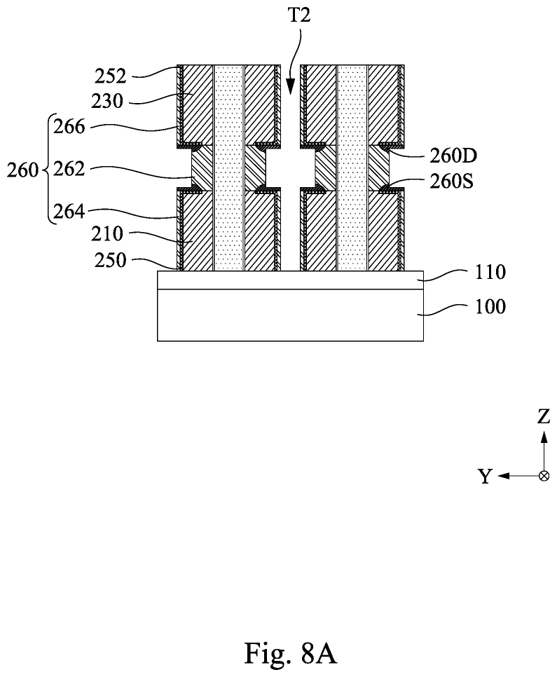

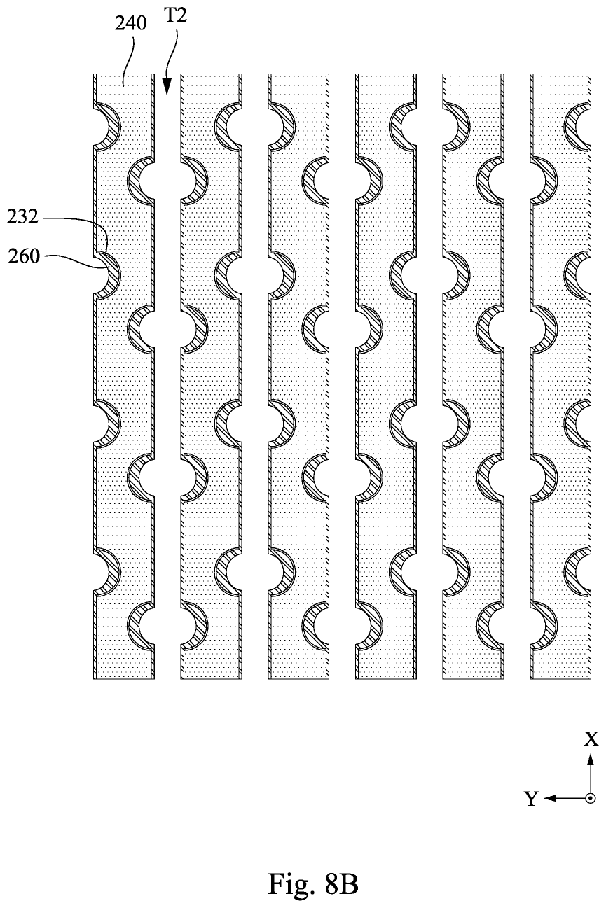

Referring to FIG. 8A and FIG. 8B, FIG. 8B is a top view of the semiconductor device respectively taken along the horizontal level of a removed silicon nitride layer 220 (see FIG. 5A) of FIG. 8A. In the present embodiment, as shown in FIGS. 7, 8A and 8B, a recessed cell integration process is performed. That is, after the first recess R1 is formed, the fourth polysilicon layer 260 is filled in the first recess R1. In greater details, the fourth polysilicon layer 260 is formed on the second polysilicon layer 210 and the third polysilicon layer 230, and formed in the first recess R1 which is between the second polysilicon layer 210 and the third polysilicon layer 230, such that the fourth polysilicon layer 260 has a concave portion 262 between the second polysilicon layer 210 and the third polysilicon layer 230.

After the fourth polysilicon layer 260 is formed, the concave portion 262 of the fourth polysilicon layer 260 is doped to define a drain region 260D and a source region 260S. A direction of the source region 260S and the drain region 260D are aligned along Z axis. In greater details, the source region 260S and the drain region 260D are formed in the fourth polysilicon layer 260 by controlling dopants of ion implantation with a specific angle, followed by an annealing process to activate the implanted dopants. In some embodiments, dopants of doping the concave portion 262 of the fourth polysilicon layer 260 to define the source region 260S and the drain region 260D may include P-type dopants or N-type dopants. For example, P-type dopants may be boron (B), BF₂ or BF₃, and N-type dopants may be phosphorous (P), arsenic (As), or antimony (Sb). In the present embodiments, the source region 260S and the drain region 260D include N-type dopants.

In some embodiments, the fourth polysilicon layer 260 covers the second polysilicon layer 210 and the third polysilicon layer 230. In some embodiments, the fourth polysilicon layer 260 further has a first portion 264 and a second portion 266 connected to the concave portion 262. The first portion 264 is disposed on the second polysilicon layer 210, the second portion 266 is disposed on the third polysilicon layer 230, and the concave portion 262 is disposed on the exposed portion of the liner layer 232. In other words, the first portion 264 and the second portion 266 protrude from the concave portion 262. In some embodiments, the first portion 264 and the second portion 266 are in contact with the source terminal contact 250 and the drain terminal contact 252, respectively.

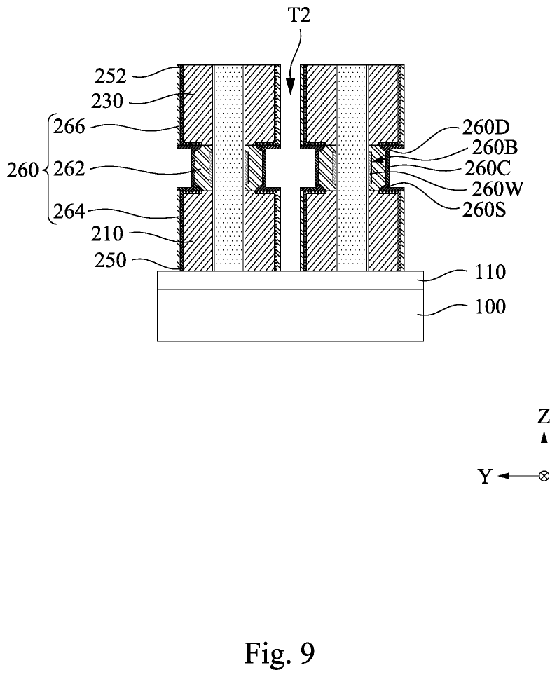

Referring to FIG. 9, after the concave portion 262 is doped to define the source region 260S and the drain region 260D, an inside of the concave portion 262 is doped to form a well region 260W. The well region 260W is a portion of a bulk region 260B. Then, the concave portion 262 is doped to define a channel region 260C and the critical voltage is adjusted by controlling doping concentration and doping range. In greater details, the channel region 260C is formed in the concave portion 262 of the fourth polysilicon layer 260 by controlling dopants of ion implantation with a specific angle, e.g., ion implantation process with a low dopant concentration, followed by an annealing process to activate the implanted dopants. The channel region 260C is between the source region 260S and the drain region 260D. In some embodiments, dopants of doping the concave portion 262 of the fourth polysilicon layer 260 to define the channel region 260C may include P-type dopants or N-type dopants. In greater details, the channel region 260C is performed by lightly doping the concave portion 262, in the present embodiments. For example, P-type dopants may be boron (B), BF₂ or BF₃, and N-type dopants may be phosphorous, arsenic (As), or antimony (Sb). In the present embodiments, the channel region 260C includes P-type dopants. The dopants of the channel region 260C may be different from the dopants of the source region 260S and the drain region 260D. In some embodiments, the concave portion 262 is defined as a main body of a memory device. In other words, the source region 260S, the drain region 260D, and the channel region 260C can serve as a transistor that acts as a portion of a memory device.

In some embodiments, the annealing process performed after the implant process is a rapid thermal annealing (RTA) process performed at a temperature in a range from about 700 Celsius to about 1500 Celsius for the duration in a range from about 5 seconds to about 250 seconds. In further embodiments, conventional furnace annealing (CFA) process may be performed at a temperature in a range from about 900 Celsius to about 1500 Celsius for duration in a range from about 30 minutes to about 6 hours.

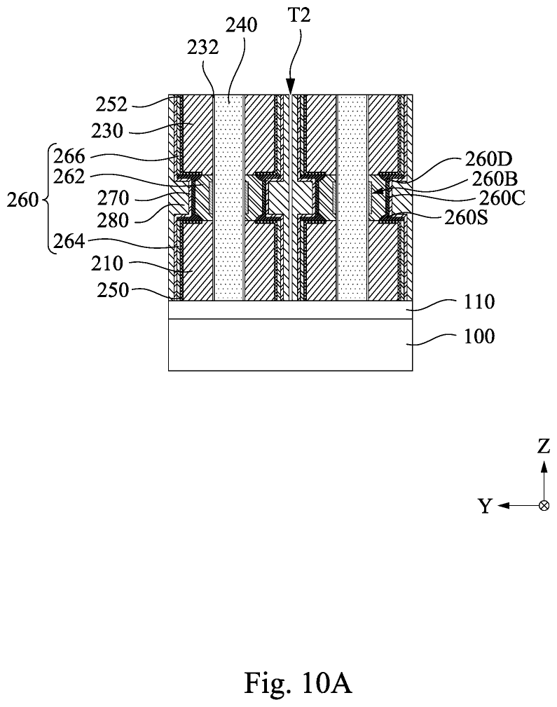

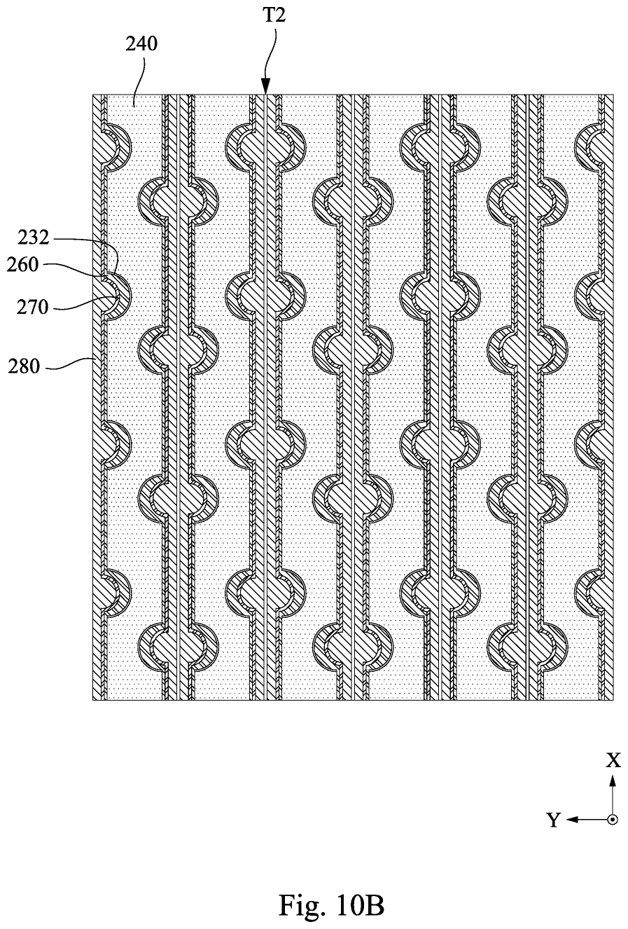

Referring to FIG. 10A and FIG. 10B, FIG. 10B is a top view of the semiconductor device respectively taken along the horizontal level of a removed silicon nitride layer 220 (see FIG. 5A) of FIG. 10A. A gate dielectric layer 270 is formed on the fourth polysilicon layer 260. Specifically, the gate dielectric layer 270 is formed on a sidewall of the fourth polysilicon layer 260. After the gate dielectric layer 270 is formed, a gate conductive layer 280 is formed on the gate dielectric layer 270, and the gate conductive layer 280 is defined as a word line. In greater details, the gate dielectric layer 270 is formed to be conformal on the sidewall of the fourth polysilicon layer 260, and the gate conductive layer 280 is formed on the gate dielectric layer 270.

In some embodiments, as shown in FIG. 10A and FIG. 10B, the gate dielectric layer 270 is disposed between the fourth polysilicon layer 260 and the gate conductive layer 280.

In some embodiments, as shown in FIG. 10B, the concave portion 262 of the fourth polysilicon layer 260 has a semi-elliptical profile, in a top view. In some embodiments, the fourth polysilicon layer 260 and the gate dielectric layer 270 have a semi-elliptical profile in the top view at the horizontal level where the silicon nitride layer 220 of FIG. 5B is removed. As a result, after the gate conductive layer 280 is formed, a portion of the gate conductive layer 280 that serves as a gate electrode of the memory device will have a corresponding shape, such as semi-ellipsoidal cylinder. In other words, the portion of the gate conductive layer 280 (i.e., the gate electrode) and the concave portion 262 of the fourth polysilicon layer 260 has the semi-elliptical profile, in the top view. However, the present disclosure is not limited thereto. The shape of the portion of the gate conductive layer 280 (i.e., the gate electrode) and the concave portion 262 of the fourth polysilicon layer 260 may have rectangular shape, square shape, triangular shape, trapezoidal shape, semi-circular shape, or other shapes, in the top view. In some embodiments, as shown in FIG. 10B, the main body (the concave portion 262) of the memory device is arranged antisymmetrically. In other words, a distribution of the main body (the concave portion 262) of the memory device in the top view forms staggered arrangement. Specifically, the main body (the concave portion 262) of the memory device is staggered on the first isolation layer 240.

In some embodiments, the gate dielectric layer 270 is made of silicon oxide, silicon nitride, aluminum oxide, or other suitable materials. In other embodiments, the gate dielectric layer 270 is made of a combination of, gate oxide (tunneling oxide), oxide and nitride structure (for example, ONO), and high k dielectric materials. In some embodiments, the material of the gate conductive layer 280 may include conductive materials and may be selected from polysilicon, polycrystalline silicon germanium (poly-SiGe), metal nitride, metal silicide, or a combination of other metal materials. For example, the metal nitride may be tungsten nitride, molybdenum nitride, titanium nitride, tantalum nitride, or a combination thereof. The metal silicide may be tungsten silicide, titanium silicide, cobalt silicide, nickel silicide, platinum silicide, erbium silicide, or a combination thereof. The metal may be copper, silver, or other suitable metals.

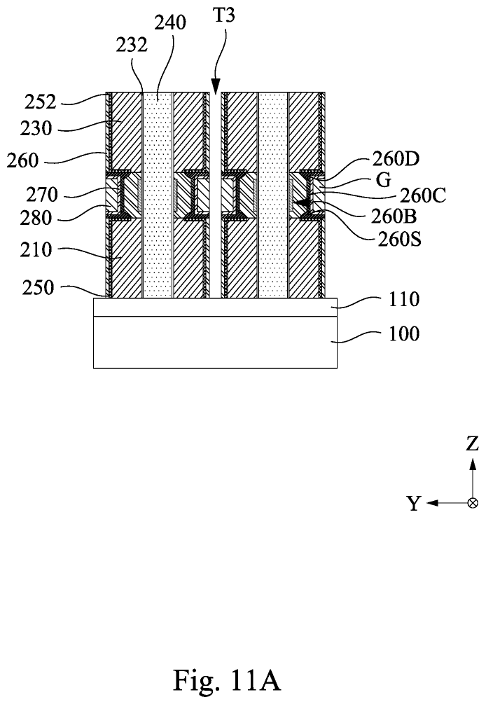

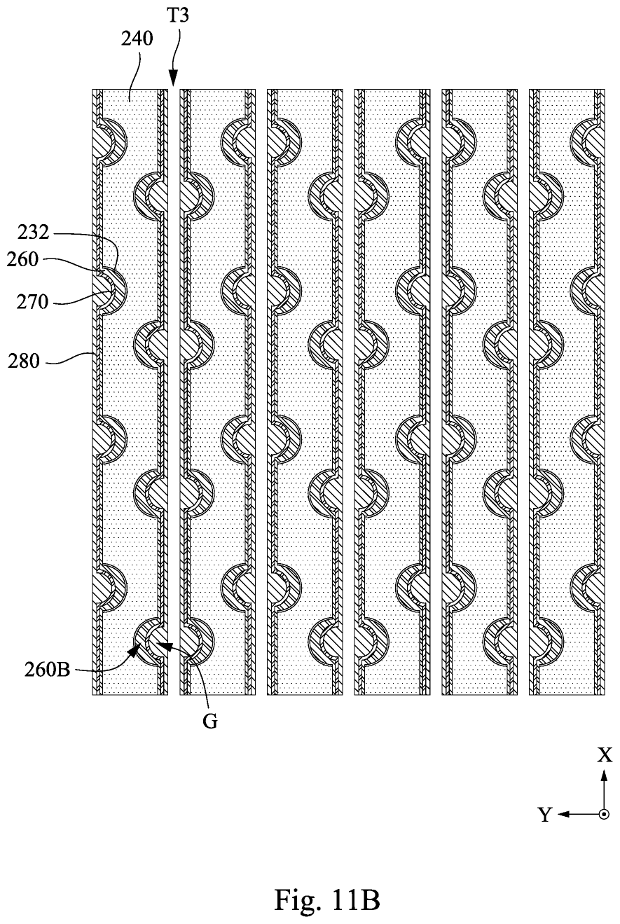

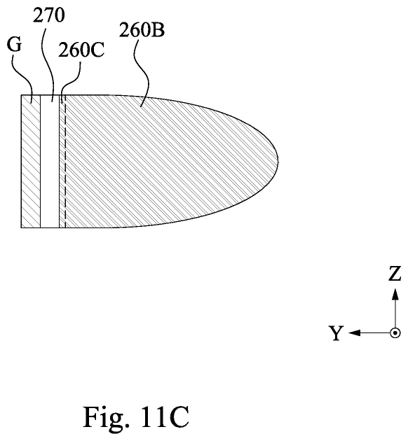

Referring to FIG. 11A and FIG. 11B, FIG. 11B is a top view of the semiconductor device respectively taken along the horizontal level of a removed silicon nitride layer 220 (see FIG. 5A) of FIG. 11A. An etching process, e.g., shallow trench isolation (STI) etching, is performed to remove portions of the fourth polysilicon layer 260, the gate dielectric layer 270, and the gate conductive layer 280. In greater details, a patterned hard mask layer may be formed by a suitable deposition, developing, and/or etching technique, and the patterned hard mask layer may be used as an etch mask to etch the fourth polysilicon layer 260, the gate dielectric layer 270, and the gate conductive layer 280 to form a third trench T3. In some embodiments, as shown in FIG. 11B, the third trench T3 has a strip shape, in the top view. In some embodiments, the gate dielectric layer 270 and the gate conductive layer 280 are formed embedded in the fourth polysilicon layer 260. In other words, the gate dielectric layer 270 and the gate conductive layer 280 are disposed on the concave portion 262 of the fourth polysilicon layer 260. In some embodiments, the gate conductive layer 280 can serve as a word line (WL), and a position of the gate conductive layer 280 facing the concave portion 262 (the first recess R1 in FIG. 7) may serve as gate G. The bulk region 260B faces toward the first isolation layer 240. In some embodiments, the bulk region 260B and the gate G respectively faces toward different positions. In greater details, the bulk region 260B faces toward the first trench T1 (see FIG. 3A and FIG. 3B), while the gate G faces toward the second trench T2 (see FIG. 8A and FIG. 8B). In other words, the bulk region 260B faces toward the first trench T1 in Fig. (see FIG. 3A and FIG. 3B), and the gate G faces toward the third trench T3 in (see FIG. 11A and FIG. 11B).

FIG. 11C is a schematic view of a memory cell of the transistor device of FIG. 11B. As shown in FIG. 11C, the memory cell includes the bulk region 260B, the channel region 260C, the gate dielectric layer 270, and the gate G. The bulk region 260B tapers in a direction away from the gate G. For example, the bulk region 260B may taper to a point toward the gate G. A shape of the bulk region 260B may be a triangle. In some embodiments, the shape of the bulk region 260B may be a semi-ellipsoid, a semi-circle, or a trapezoid.

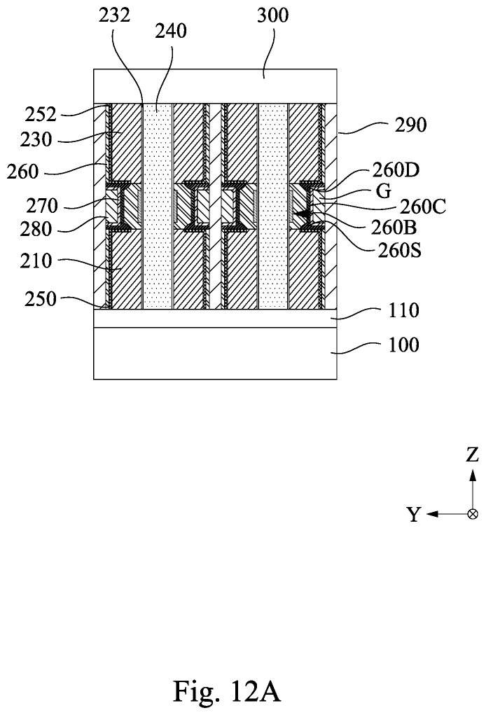

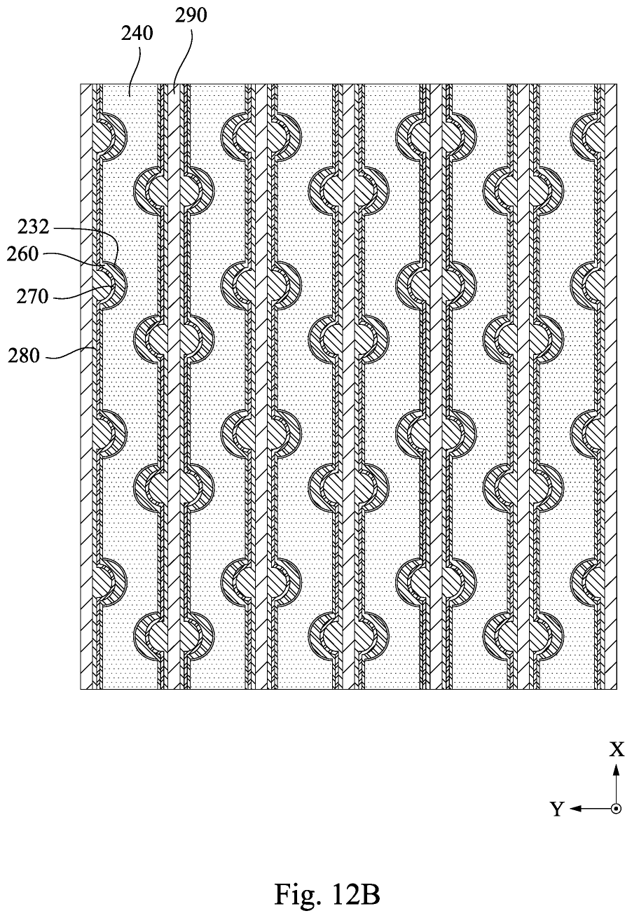

Referring to FIG. 12A and FIG. 12B, FIG. 12B is a top view of the semiconductor device respectively taken along the horizontal level of a removed silicon nitride layer 220 (see FIG. 5A) of FIG. 12A. The third trench T3 of FIG. 11A and FIG. 11B is filled with insulating materials to form second isolation layer 290. In other words, the second isolation layer 290 is formed on the fourth polysilicon layer 260. In greater details, the second isolation layer 290 covers the fourth polysilicon layer 260 and the gate conductive layer 280. In some embodiments, a length direction of the second isolation layer 290 is parallel to a length direction of the first isolation layer 240. In some embodiments, as shown in FIG. 12B, the second isolation layer 290 is alternately arranged with the first isolation layer 240, in the top view. In some embodiments, as shown in FIG. 12B, the second isolation layer 290 has a strip shape, while the first isolation layer 240 has a serpentine shape, in the top view. In some embodiments, the bulk region 260B faces toward the first isolation layer 240, while the gate G faces toward the second isolation layer 290. In other words, the bulk region 260B and the gate G are disposed on two opposite sides of the gate dielectric layer 270.

In some embodiments, the second isolation layer 290 includes silicon oxide layer, silicon nitride layer or silicon oxynitride layer, and the like. The second isolation layer 290 may be made of low-k dielectric material, such as tetraethoxysilane (TEOS). The second isolation layer 290 may be formed by CVD, PECVD, ALD, FCVD, LPCVD, or other suitable methods. In some embodiments, after the second isolation layer 290 is formed, a planarization process, such as a CMP process, may be performed to remove excess materials of the second isolation layer 290.

Referring to FIG. 12A, after the second isolation layer 290 is formed, a third isolation layer 300 is formed on the stack 200 (see FIG. 5A). In other words, the third isolation layer 300 is formed on the second isolation layer 290 and the fourth polysilicon layer 260. Stated differently, the third isolation layer 300 is formed on the first isolation layer 240 and the second isolation layer 290. In some embodiments, the third isolation layer 300 is perpendicular to the second isolation layer 290. In other words, a length direction of the third isolation layer 300 is perpendicular to a length direction of the fourth polysilicon layer 260. In some embodiments, the third isolation layer 300 is an inter-metal dielectric (IMD) layer. The third isolation layer 300 may be made of a low dielectric material. For example, the low dielectric material may be a doped oxide, such as phosphor silicate glass (PSG), boron phosphor silicate glass (BPSG), or other suitable materials.

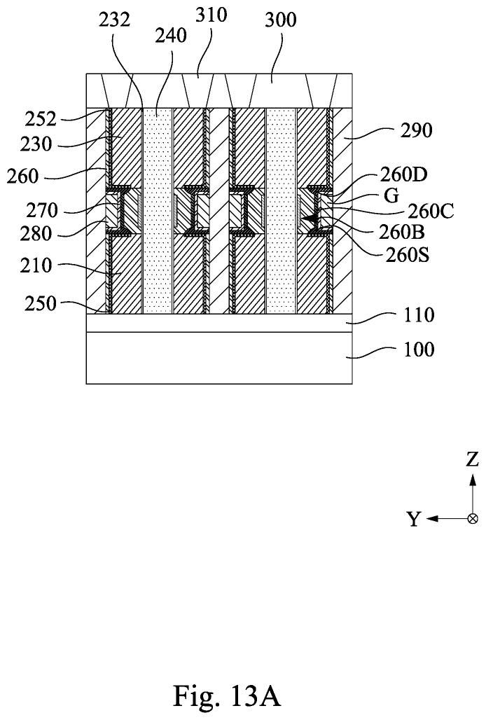

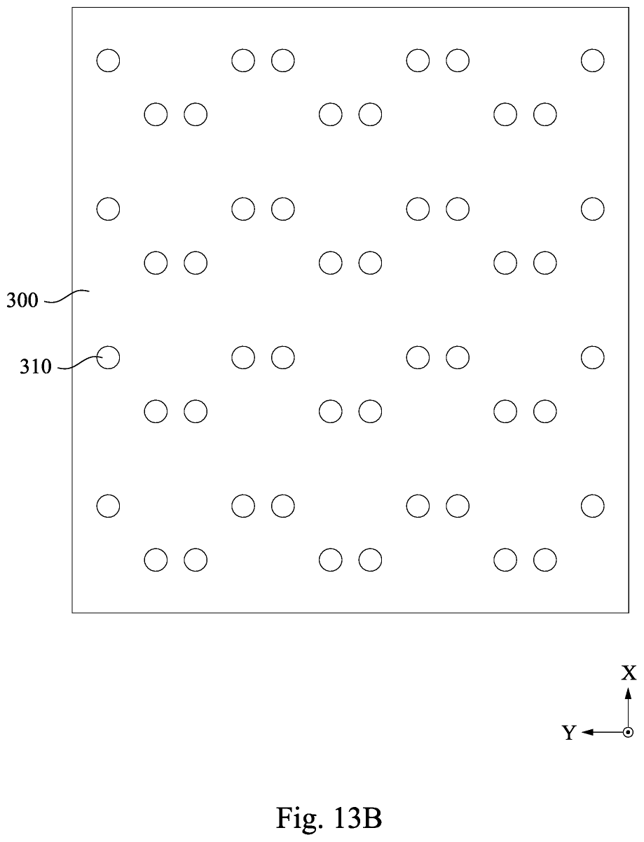

Referring to FIG. 13A and FIG. 13B, FIG. 13B is a top view of the semiconductor device taken along a horizontal level of a first via contact 310 of FIG. 13A. The first via contact 310 is formed in the third isolation layer 300, and the first via contact 310 is in contact with the drain terminal contact 252. In greater details, the method of forming the first via contact 310 may include etching the third isolation layer 300 to form a via hole, and then filling conductive materials in the via hole. For example, tungsten can be filled into the via hole by chemical vapor deposition (CVD) to form the first via contact 310. In some embodiments, the first via contact 310 is aligned with the drain terminal contact 252. In other words, a bottom surface of the first via contact 310 is in contact with a top surface of the drain terminal contact 252. In other embodiments, the bottom surface of the first via contact 310 is in contact with top surfaces of the drain terminal contact 252 and the third polysilicon layer 230, wherein the top surface of the drain terminal contact 252 is coplanar with the top surface of the third polysilicon layer 230.

In some embodiments, after the first via contact 310 is formed, a planarization process, such as a CMP process, may be performed to remove excess materials of the first via contact 310.

In some embodiments, before the first via contact 310 is formed, a barrier layer is formed on an inner wall of the via hole. In greater details, the barrier layer may be formed by sputtering deposit, and the barrier layer may be made of, for example, titanium nitride (TiN). In some embodiments, the first via contact 310 may be made of a metal, such as tungsten.

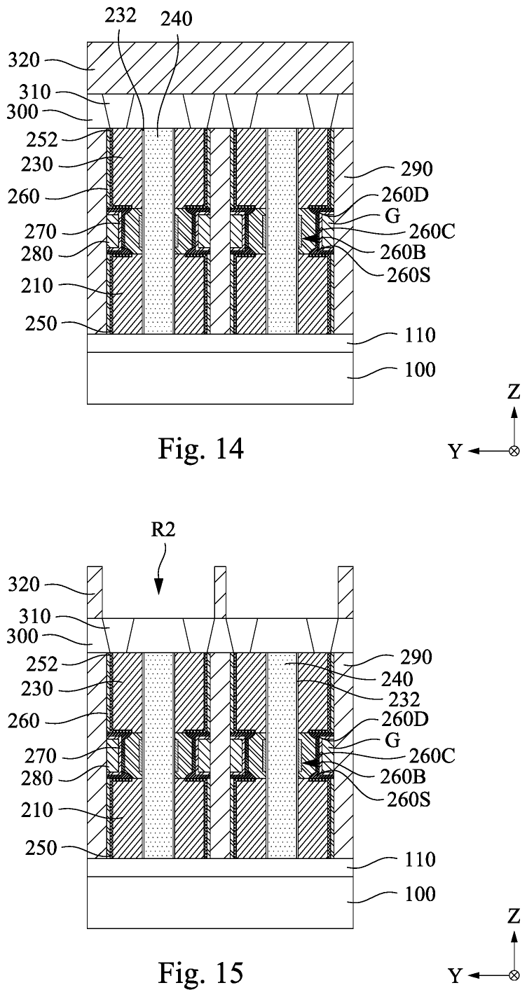

Referring to FIG. 14, a fourth isolation layer 320 is formed on the third isolation layer 300. In greater details, the fourth isolation layer 320 covers the first via contact 310 and the third isolation layer 300. In some embodiments, a length direction of the fourth isolation layer 320 is parallel to a length direction of the third isolation layer 300, and perpendicular to the length direction of the second isolation layer 290. In some embodiments, the fourth isolation layer 320 is an inter-metal dielectric (IMD) layer. The fourth isolation layer 320 may be made of a low dielectric material. For example, the low dielectric material may be a doped oxide, such as phosphor silicate glass (PSG), boron phosphor silicate glass (BPSG), or other suitable materials.

Referring to FIG. 15, the fourth isolation layer 320 is etched to form a second recess R2. In greater details, a second recess R2 is formed to expose the first via contact 310. As a result, when conductive materials are filled in the second recess R2 on subsequent process, the conductive materials are in contact with the first via contact 310.

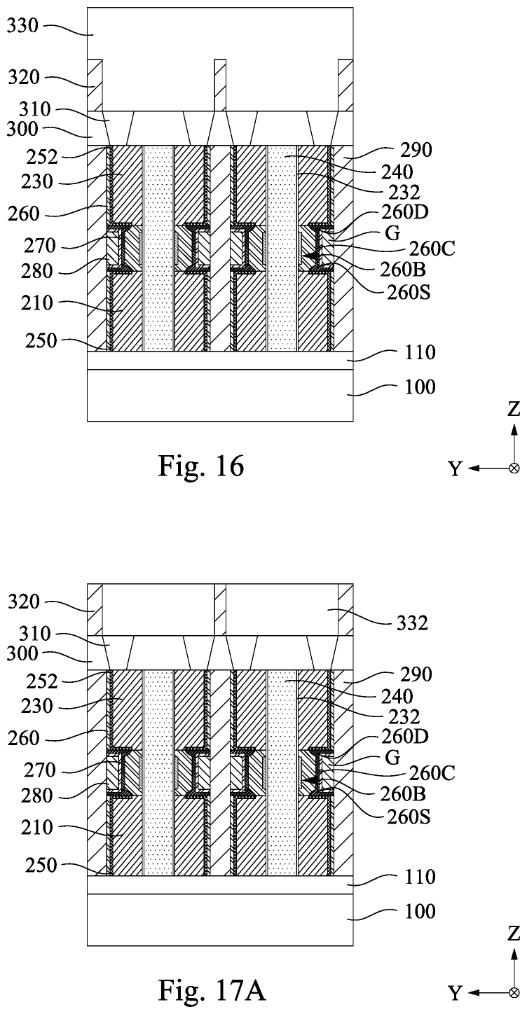

Referring to FIG. 15 and FIG. 16, conductive materials 330 are filled in the second recess R2. In greater details, a portion of the conductive materials 330 is disposed in the fourth isolation layer 320, and the other portion of the conductive materials 330 is disposed on the fourth isolation layer 320. In other words, the conductive materials 330 cover the fourth isolation layer 320, and a portion of the conductive materials 330 is embedded in the fourth isolation layer 320. In some embodiments, after the conductive materials 330 is formed, a planarization process, such as a CMP process, may be performed to remove excess materials of the conductive materials 330 and the fourth isolation layer 320.

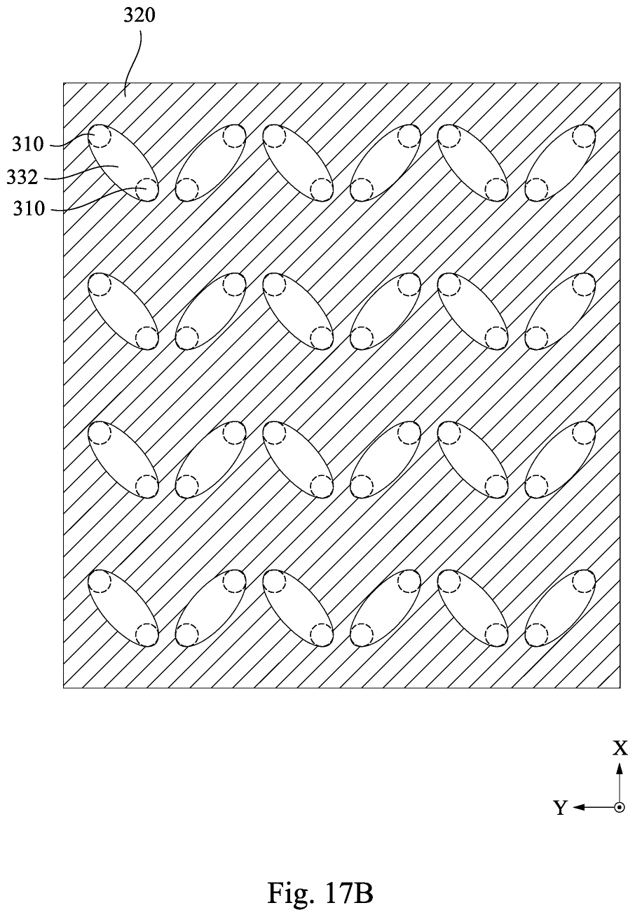

Referring to FIG. 17A and FIG. 17B, FIG. 17B is a top view of the semiconductor device taken along a horizontal level of an interconnect conductive pad 332 of FIG. 17A. For convenience of explanation, dashed lines in FIG. 17B are used to illustrate the first via contact 310. As shown in FIGS. 15, 16, 17A and 17B, after the conductive materials 330 are filled in the second recess R2, the fourth isolation layer 320 and the conductive materials 330 are performed a planarization process to form the interconnect conductive pad 332. In greater details, the interconnect conductive pad 332 is disposed in the fourth isolation layer 320, and the interconnect conductive pad 332 is in contact with the first via contact 310. In some embodiments, a bottom surface of the interconnect conductive pad 332 is coplanar with a top surface of the first via contact 310.

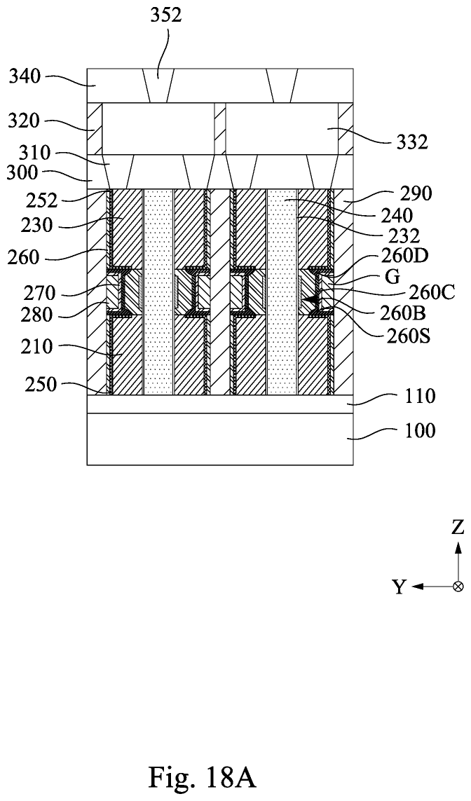

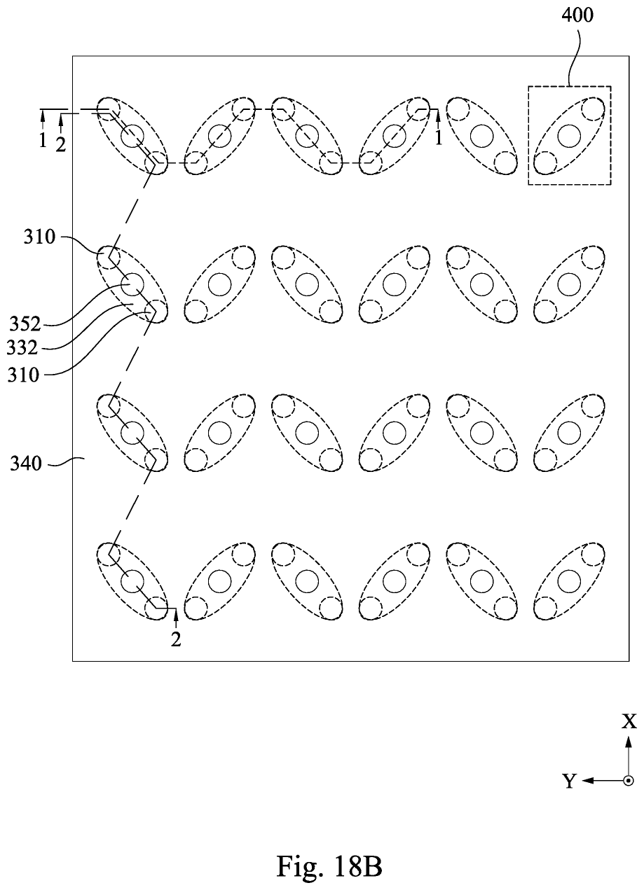

Referring to FIG. 18A and FIG. 18B, FIG. 18B is a top view of the semiconductor device taken along a horizontal level of a second via contact 352 of FIG. 18A. For convenience of explanation, dashed lines in FIG. 18B are used to illustrate the first via contact 310 and the interconnect conductive pad 332.

A fifth isolation layer 340 is formed on the fourth isolation layer 320 and the interconnect conductive pad 332. In other words, the fifth isolation layer 340 covers the fourth isolation layer 320 and the interconnect conductive pad 332. After the fifth isolation layer 340 is formed, a suitable etching process may be performed to etch the fifth isolation layer 340, such that the fifth isolation layer 340 has a via hole. Then, conductive materials are filled in the via hole of the fifth isolation layer 340 to form the second via contact 352. In some embodiments, the fifth isolation layer 340 may be made of a low dielectric material. For example, the low dielectric material may be a doped oxide, such as phosphor silicate glass (PSG), boron phosphor silicate glass (BPSG), or other suitable materials.

In some embodiments, before the second via contact 352 is formed, a barrier layer is formed on an inner wall of the via hole. In greater details, the barrier layer may be formed by sputtering deposit, and the barrier layer may be made of, for example, titanium nitride (TiN). In some embodiments, the second via contact 352 may be made of a metal, such as tungsten.

In some embodiments, after the second via contact 352 is formed, a planarization process, such as a CMP process, may be performed to remove excess materials of the second via contact 352.

In some embodiments, the interconnect conductive pad 332 is connected to the first via contact 310 and the second via contact 352. In other words, the interconnect conductive pad 332 is in contact with the first via contact 310 and the second via contact 352.

In some embodiments, a vertical projection region of the first via contact 310 on the substrate 100 is not fully overlapped with a vertical projection region of the second via contact 352 on the substrate 100. In other words, the vertical projection region of the first via contact 310 on the substrate 100 is partially overlapped with or not overlapped with the vertical projection region of the second via contact 352 on the substrate 100.

In some embodiments, the first via contact 310 and the second via contact 352 may be made same materials. For example, the first via contact 310 and the second via contact 352 may be made of tungsten.

In some embodiments, the first via contact 310, the interconnect conductive pad 332, and the gate conductive layer 280 are defined as a group of a NOR flash memory cell 400. The group of the NOR flash memory cell 400 includes two NOR flash memory cells. An area density of each of the NOR flash memory cells is less than six times a square of a feature size (F²), per cell.

The area density of each of the NOR flash memory cells may be calculated by an equation (1) below. For example, the area density of each of the NOR flash memory cells may be 5 F². By using the above mentioned structure of the semiconductor device, a density of the semiconductor device can be increased, thereby improving a performance of the semiconductor device.

9/4× 18/4+2=5.0625 F² (1)

In some embodiments, one NOR flash memory cell 400 (located on one first isolation layer 240) and another NOR flash memory cell 400 (located on another first isolation layer 240) are arranged antisymmetrically with each other to increase the density of the structure.

In some embodiments, the NOR flash memory cell 400 may be connected in parallel. In greater details, the second via contact 352 is connected to the underlying interconnect conductive pad 332, and the interconnect conductive pad 332 is connected to the underlying first via contact 310 which is in parallel. Then, the two adjacent first via contacts 310 are respectively connected to the underlying drain terminal contacts 252, and connected through the main body of the memory device (concave portion 262 in FIG. 9) and the source terminal contact 250 to the first polysilicon layer 110 serving as the common ground line.

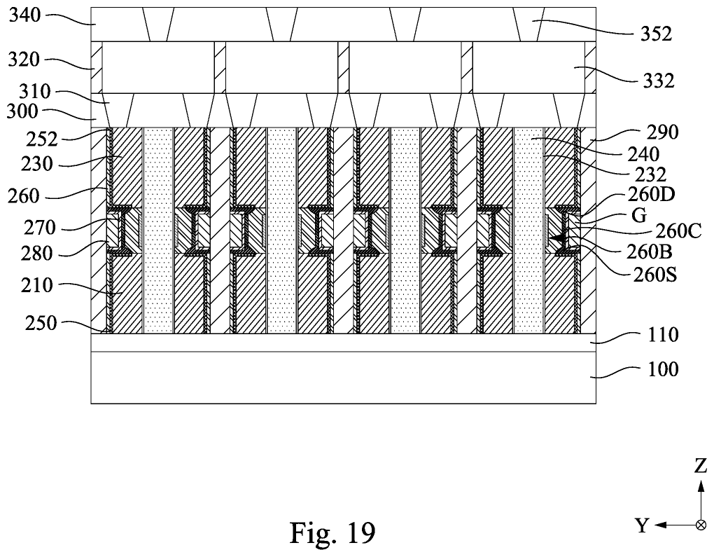

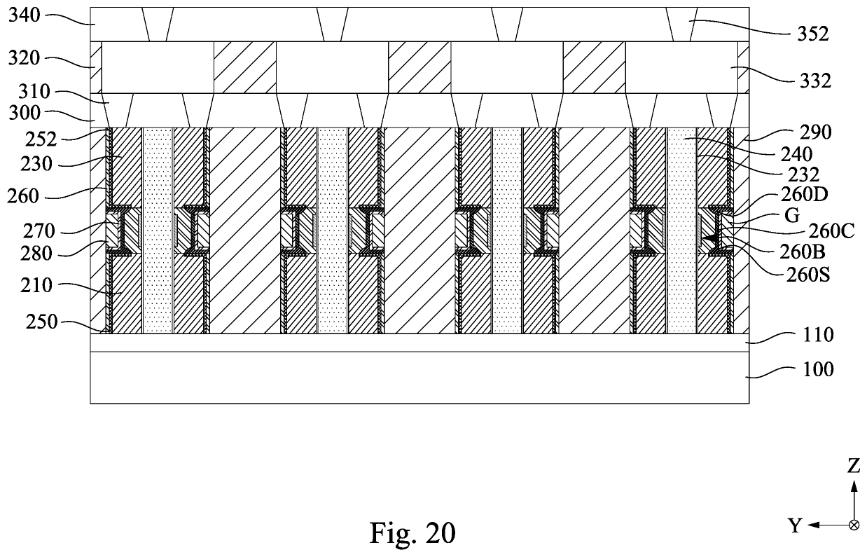

FIG. 19 is a cross-sectional view of the semiconductor device taken along line 1-1 of FIG. 18B. FIG. 20 is a cross-sectional view of the semiconductor device taken along line 2-2 of FIG. 18B. Referring to FIG. 19 and FIG. 20, the interconnect conductive pad 332 is connected to the underlying first via contact 310, and the second via contact 352 is disposed on the interconnect conductive pad 332.

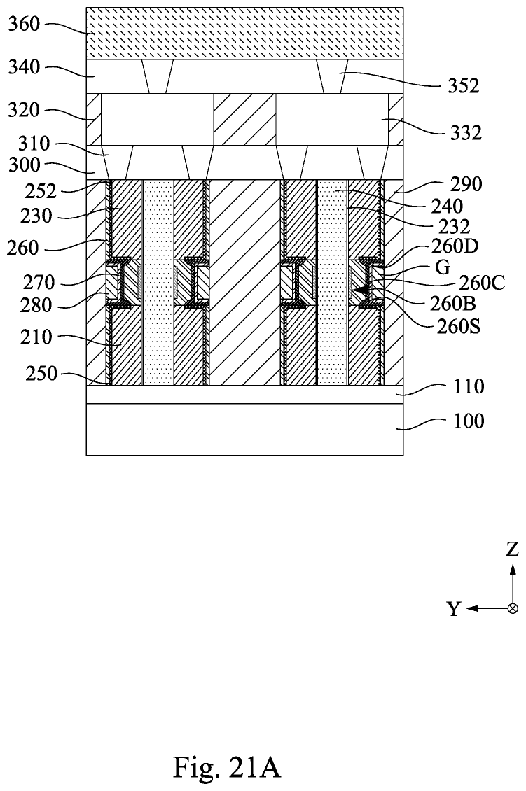

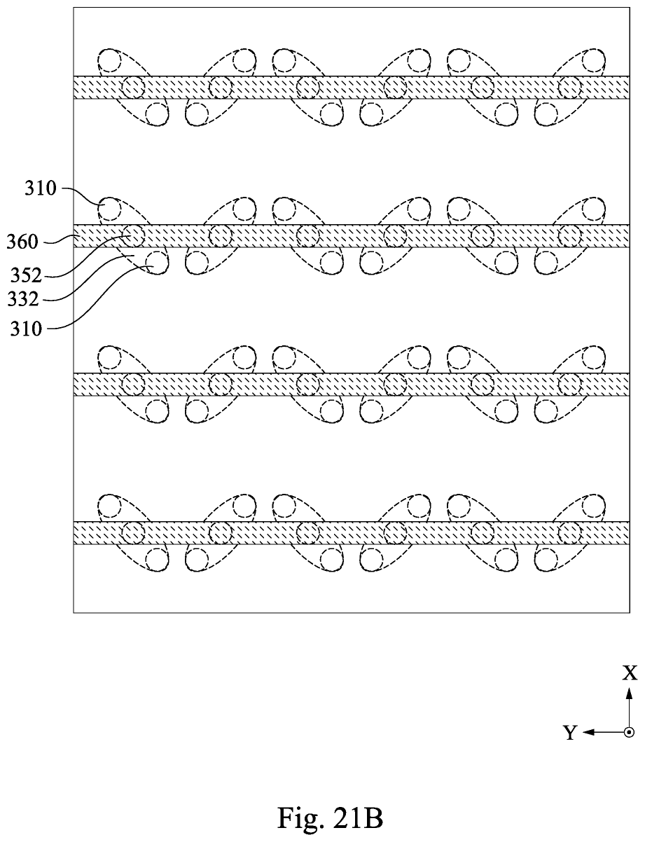

Referring to FIG. 21A and FIG. 21B, FIG. 21B is a top view of the semiconductor device taken along a horizontal level of a drain conductive layer 360 of FIG. 21A. For convenience of explanation, dashed lines in FIG. 21B are used to illustrate the first via contact 310, the interconnect conductive pad 332 and the second via contact 352. The drain conductive layer 360 is formed on the fifth isolation layer 340 and the second via contact 352. The drain conductive layer 360 in FIG. 21A may be patterned and defined as a bit line in FIG. 21B. It is to be noted that a sixth isolation layer adjacent the conductive layer 360 is omitted in order to simplify, as shown in FIG. 21A, in which the sixth isolation layer is coplanar with the conductive layer 360. In some embodiments, after the drain conductive layer 360 is formed, a planarization process, such as a CMP process, may be performed to remove excess materials of the drain conductive layer 360.

In some embodiments, after the drain conductive layer 360 is formed, a seventh isolation layer is formed serving as a protective layer. In other words, the seventh isolation layer covers the drain conductive layer 360 and the aforementioned sixth isolation layer. In some embodiments, the seventh isolation layer includes a silicon oxide layer, a silicon nitride layer, a silicon oxynitride layer, or the like. In some embodiments, after the seventh isolation layer is formed, a planarization process, such as a CMP process, may be performed to remove excess materials. In some embodiments, the NOR flash memory cell manufacturing method may be a multilayer stacking process. In other words, the substrate 100, the first polysilicon layer 110, and the subsequent processes may be formed on the seventh isolation layer.

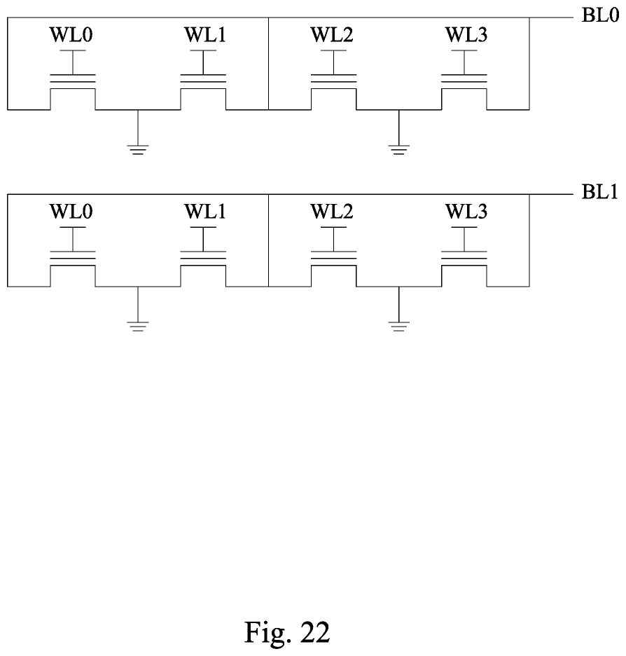

Referring to FIG. 22, FIG. 22 is a circuit diagram of a NOR flash memory cell array in accordance with some embodiments of the present disclosure. The gate of the NOR flash memory cell on the first column is connected to the first word line WL0, and the gate of the NOR flash memory cell on the second column is connected to the second word line WL1. The aforementioned gate G of the gate conductive layer 280 may act as the first word line WL0 and the second word line WL1. Similarly, the gate of the NOR flash memory cell on the third column is connected to the third word line WL2, and the gate of the NOR flash memory cell on the fourth column is connected to the fourth word line WL3. The drain of the NOR flash memory cell of the first row is connected to the first bit line BL0, and the source of the NOR flash memory cell of the second row is connected to the second bit line BL1. The aforementioned drain conductive layer 360 may act as the first bit line BL0 and the second bit line BL1.

In summary, the disclosure provides the semiconductor device and the fabrication method of the semiconductor device. By using the aforementioned semiconductor device, a density of the semiconductor device can be increased, thereby improving a performance of the semiconductor device.

It will be apparent to those skilled in the art that various modifications and variations can be made to the structure of the present disclosure without departing from the scope or spirit of the invention. In view of the foregoing, it is intended that the present disclosure cover modifications and variations of this invention provided they fall within the scope of the following claims.

What is claimed is:

1. A method of forming a semiconductor device, comprising:
forming a stack of a first polysilicon layer, a silicon nitride layer, and a second polysilicon layer;
forming a first trench penetrating the stack, wherein the first trench has a serpentine shape, in a top view;
filling a first isolation layer in the first trench;
forming a second trench penetrating the stack to expose sidewalls of the first polysilicon layer, the silicon nitride layer, and the second polysilicon layer;
removing the silicon nitride layer to form a first recess between the first polysilicon layer and the second polysilicon layer;
doping exposed sidewalls of the first polysilicon layer and the second polysilicon layer to define a source terminal contact and a drain terminal contact;
forming a third polysilicon layer on the first polysilicon layer, the second polysilicon layer, and in the first recess between the first polysilicon layer and the second polysilicon layer, such that the third polysilicon layer has a concave portion between the first polysilicon layer and the second polysilicon layer;
doping the concave portion to define a source region and a drain region;
doping an inside of the concave portion to form a well region, the well region serving as a bulk region, wherein the bulk region faces toward the first trench;
doping the concave portion to define a channel region, wherein the concave portion is defined as a main body of a memory device;
forming a gate dielectric layer on the third polysilicon layer;
forming a gate conductive layer on the gate dielectric layer, wherein the gate conductive layer is defined as a word line, and the gate conductive layer in the first recess serves as a gate which faces toward the second trench; and
forming a second isolation layer on the gate conductive layer.

2. The method of claim 1, further comprising:
forming a third isolation layer on the first isolation layer and the second isolation layer;
etching the third isolation layer to form a first via hole;
filling conductive materials in the first via hole to form a first via contact, wherein the first via contact is disposed on the drain terminal contact;
forming a fourth isolation layer on the third isolation layer;
etching the fourth isolation layer to form a second recess;
filling conductive materials in the second recess to form an interconnect conductive pad, wherein the interconnect conductive pad is disposed in the fourth isolation layer;
forming a fifth isolation layer on the fourth isolation layer and the interconnect conductive pad;
etching the fifth isolation layer to form a second via hole; and
filling conductive materials in the second via hole to form a second via contact.

3. The method of claim 2, further comprising:
forming a drain conductive layer on the fifth isolation layer and the second via contact, wherein the drain conductive layer is defined as a bit line.

4. The method of claim 1, wherein a length direction of the second isolation layer is parallel to a length direction of the first isolation layer.

5. The method of claim 1, wherein the third polysilicon layer further has a first portion and a second portion connected to the concave portion, the first portion and the second portion are respectively on the first polysilicon layer and the second polysilicon layer.

6. The method of claim 3, wherein the interconnect conductive pad is connected to the first via contact and the second via contact.

7. The method of claim 2, wherein the first via contact is aligned with the drain terminal contact.

8. A semiconductor device, comprising:
a substrate;
a first polysilicon layer and a second polysilicon layer on the substrate;
a third polysilicon layer between the first polysilicon layer and the second polysilicon layer, wherein the third polysilicon layer has a concave portion, the concave portion is between the first polysilicon layer and the second polysilicon layer, and the concave portion is defined as a main body of a memory device, and wherein the main body comprises a source region, a drain region, a channel region, and a bulk region;
a first isolation layer adjacent with the first polysilicon layer, the second polysilicon layer, and the third polysilicon layer, wherein the first isolation layer has a serpentine shape, in a top view;
a gate dielectric layer and a gate conductive layer embedded in the third polysilicon layer, wherein the gate conductive layer facing toward the concave portion serves as a gate; and
a second isolation layer on the gate conductive layer and the third polysilicon layer, wherein the bulk region and the gate respectively face toward the first isolation layer and the second isolation layer.

9. The semiconductor device of claim 8, further comprising:
a third isolation layer on the first isolation layer and the second isolation layer;
a first via contact on the third isolation layer;
a fourth isolation layer on the third isolation layer;
an interconnect conductive pad in the fourth isolation layer;
a fifth isolation layer on the fourth isolation layer; and
a second via contact in the fifth isolation layer.

10. The semiconductor device of claim 9, wherein the interconnect conductive pad is in contact with the first via contact and the second via contact.

11. The semiconductor device of claim 9, wherein the first via contact and the second via contact are made of same materials.

12. The semiconductor device of claim 9, wherein the first via contact, the interconnect conductive pad, and the gate conductive layer are defined as a group of a NOR flash memory cell, the group includes two NOR flash memory cells, and an area density of each of the NOR flash memory cells is less than six times a square of a feature size, per cell.

13. The semiconductor device of claim 9, further comprising:
a drain conductive layer on the fifth isolation layer and the second via contact, wherein the drain conductive layer is defined as a bit line.

14. The semiconductor device of claim 8, wherein the first isolation layer has a serpentine shape, and the main body of the memory device is arranged antisymmetrically on the first isolation layer, in the top view.

15. The semiconductor device of claim 8, wherein the second isolation layer has a strip shape, in the top view.

16. The semiconductor device of claim 8, further comprising:
a fourth polysilicon layer on the substrate, wherein the fourth polysilicon layer is defined as a common ground line.

17. The semiconductor device of claim 8, wherein the third polysilicon layer covers the first polysilicon layer and the second polysilicon layer, and wherein the concave portion of the third polysilicon layer has a semi-elliptical profile, in the top view.

18. The semiconductor device of claim 8, wherein an edge of the third polysilicon layer is aligned with an edge of the gate conductive layer.

19. The semiconductor device of claim 9, a vertical projection region of the first via contact on the substrate is not fully overlapped with a vertical projection region of the second via contact on the substrate.
